(19) United States
(12) Patent Application Publication
(10) Pub. No.: US 2025/0098214 A1
(43) Pub. Date: Mar. 20, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Yao-Wen HSU, Hsinchu (TW); Chun-Cheng CHOU, Hsinchu (TW)

(73) Assignee: Taiwan Semiconductor Manufacturing Company, Ltd., Hsinchu (TW)

(21) Appl. No.: 18/368,387

(22) Filed: Sep. 14, 2023

(51) Int. Cl. H01L 29/417; H01L 21/8238; H01L 27/092; H01L 29/06; H01L 29/423; H01L 29/49; H01L 29/66; H01L 29/775; H01L 29/78; H01L 29/786

(52) U.S. Cl. CPC H10D 30/6729; H10D 30/014; H10D 30/024; H10D 30/43; H10D 30/6211; H10D 30/6735; H10D 30/6757; H10D 62/121; H10D 64/668; H10D 84/017; H10D 84/0193; H10D 84/038; H10D 84/853

(57) ABSTRACT

A semiconductor device is provided, including a substrate, a transistor structure, a metal silicide layer, and a metal silicon nitride layer. The transistor structure is formed on the substrate. The transistor structure includes a source region, a drain region and a gate structure. The gate structure is located between the source region and the drain region. The metal silicide layer is formed on the top surface of the source region and the top surface of the drain region, and the metal silicon nitride layer is formed on the surface of the metal silicide layer.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

For manufacturing different conductive layers on the substrate, the self-aligned contact (SAC) process may be utilized to avoid misalignment. However, the integrated fabrication also brings out some issues, such as reliability, high capacitance, or high resistance. Therefore, there is a need in the art to provide improved devices or methods that can address the issues mentioned above.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D are schematic views of a semiconductor device in a cross-sectional direction according to an embodiment of the present disclosure.

FIGS. 2A to 2D are schematic views of a semiconductor device in another cross-sectional direction according to an embodiment of the present disclosure.

FIGS. 3A and 3B are schematic views of a semiconductor device in a cross-sectional direction according to another embodiment of the present disclosure.

FIG. 4 is a flow chart of a method for forming a semiconductor device according to an embodiment of the disclosure.

FIG. 5 is a schematic view showing a spine-like metal silicide layer electrically connected to a source/drain contact.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

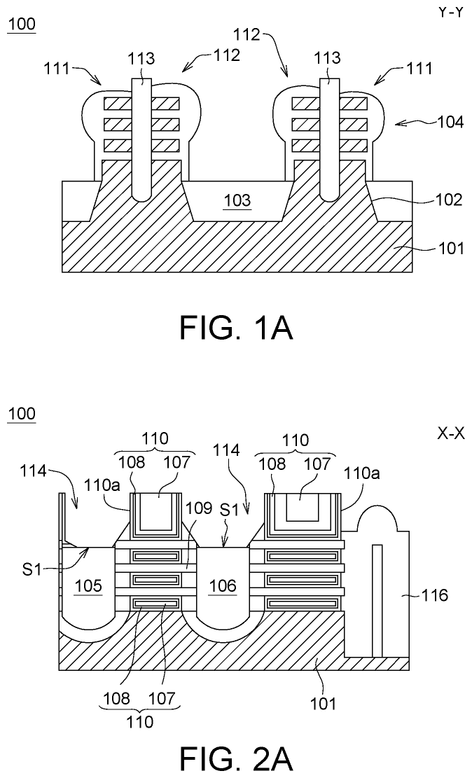

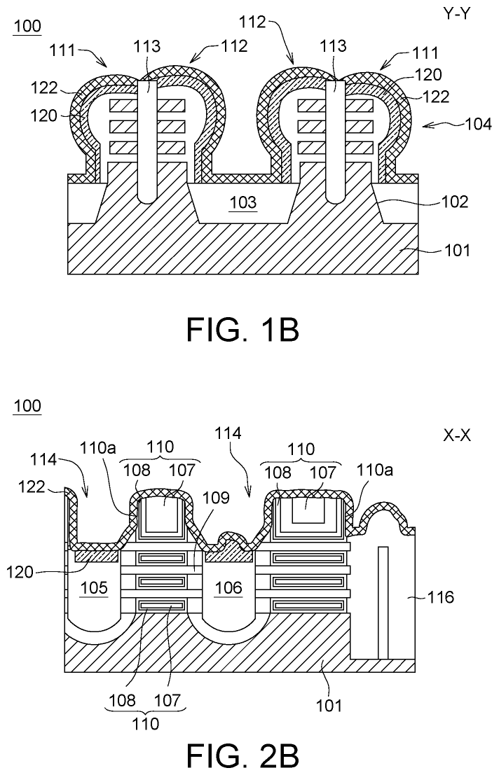

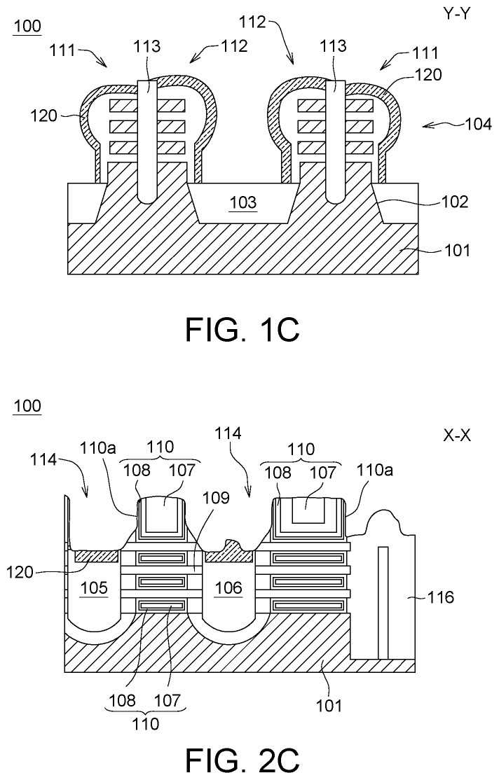

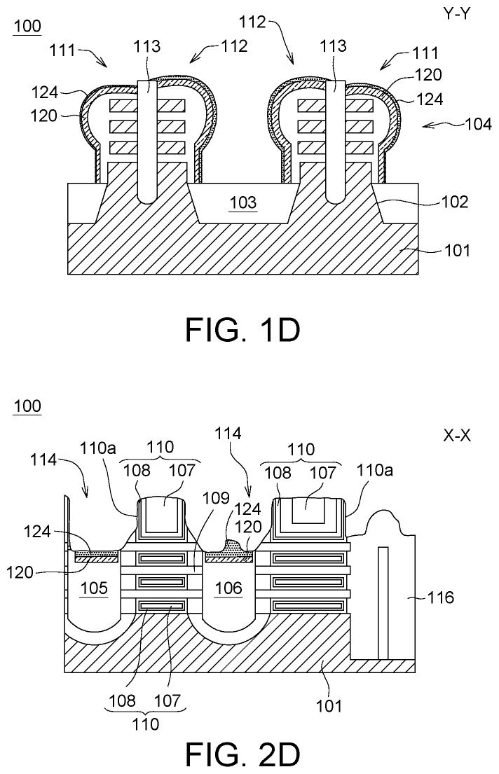

Referring to FIGS. 1A to 1D and FIGS. 2A to 2B, wherein FIGS. 1A to 1D show schematic views of a semiconductor device 100 in a cross-sectional direction according to an embodiment of the present disclosure, and FIGS. 2A to 2D show schematic views of a semiconductor device 100 in another cross-sectional direction according to an embodiment of the present disclosure. FIGS. 1B to 1D are schematic cross-sectional views of various parts of the transistor structure 104 of the semiconductor device 100 shown in FIG. 1A, and correspond to various process stages of the metal silicide layer 120 and the metal silicon nitride layer 124 forming on the transistor structure 104 of the semiconductor device 100. In addition, FIG. 2B to FIG. 2D are schematic cross-sectional views of various parts of the transistor structure 104 of the semiconductor device 100 shown in FIG. 2A and correspond to various process stages of the metal silicide layer 120 and the metal silicon nitride layer 124 forming on the transistor structure 104 of the semiconductor device 100. In addition, the cross section Y-Y shown in the figures is along the plane of the channel region of the gate structure 110 with source/drain regions 105 and 106 on both sides thereof. The cross section X-X is perpendicular to the plane of the section Y-Y and passes through the source/drain regions 105 and 106.

The semiconductor device 100 of the present embodiment can be applied in the fin-based transistor structure 104, which includes a channel region extending on a three-dimensional fin-based structure 102 of the semiconductor substrate 101. The fin-based transistor structure 104 may include fin field effect transistors (finFETs) or nanostructure transistors (such as nanowire transistors, nanosheet transistors, gate-all-around (GAA) transistors, multi-bridge channel transistors, nanoribbon transistors etc.). The fins of semiconductor material are surrounded by a gate structure 110 configured to control the flow of charge carriers in the channel region.

For example, in a finFET, the gate structure 110 wraps around three sides of the fin (and the channel region), thereby allowing increased control over the channel region (and switching of the finFET). The gate structure 110 includes a gate electrode layer 107 and a gate dielectric layer 108, and the gate electrode layer 107 overlaps with the gate dielectric layer 108. The gate structure 110 is formed between the source region 103 and the drain region 104 and above the channel region 105. The interface layer of the gate dielectric layer 108 may include a dielectric material, such as a silicon oxide layer (SiO₂) or a silicon oxynitride (SiON). The high-K dielectric layer of the gate dielectric layer 108 may include HfO₂, TiO₂, HfZrO, Ta₂O₃, HfSiO₄, ZrO₂, ZrSiO₂, combinations thereof, or other suitable materials.

The gate electrode layer 107 may include a first group of metal materials for N-type FinFET 111 and a second group of metal materials for P-type FinFET 112. Accordingly, FinFET devices may include a dual work-function metal gate configuration.

As another example, in the nanostructure transistor, the gate structure 110 surrounds the plurality of channel regions in the fin, so that the gate structure 110 surrounds each semiconductor layer 109 in the plurality of channel regions. The semiconductor layer 109 of the nanosheet-like device may include any suitable shape and/or configuration. For example, the semiconductor layer 109 can be one of many different shapes, such as a wire (or nanowire), a sheet (or nanosheet), a rod (or nanorod), and/or other suitable shapes. In other words, the term nanosheet-like device broadly includes devices having a semiconductor layer 109 of nanowires, nanorods, and any other suitable shape. The semiconductor layer 109 connects a pair of source/drain regions 105 and 106 such that charge carriers can flow from the source region 105 through the semiconductor layer 109 to the drain region 106 during operation (e.g., when the transistor is turned on). In addition, a gate dielectric layer 108 is formed between the source/drain regions 105 and 106 and the gate electrode layer 107, so that the source/drain regions 105 and 106 can be shielded when operating the gate electrode layer 107. In the present disclosure, for example, atomic layer deposition (ALD) or chemical vapor deposition (CVD) is used to deposit the inner spacer material on the sidewall of the gate dielectric layer 108, and then form the source/drain regions 105 and 106 on opposite sides of the semiconductor layer 109.

Referring to FIGS. 1A and 2A, the semiconductor device 100 includes a substrate 101 and a transistor structure 104, the transistor structure 104 is formed on the substrate 101, and the transistor structure 104 includes a source region 105, a drain region 106 and a gate structure 110 located between the source region 105 and the drain region 106. That is, source/drain regions 105 and 106 (e.g., epitaxial regions) are located on both sides of the gate structure 110. In some embodiments, the transistor structure 104 includes a p-type metal oxide semiconductor (PMOS) region, an n-type metal oxide semiconductor (NMOS) region, and/or a complementary metal oxide semiconductor (CMOS) region. In addition, the transistor structure 104 may include an N-type field effect transistor 111 (NFET) and a P-type field effect transistor 112 (PFET). In one embodiment, as shown in FIG. 1A, the NFET 111 and the PFET 112 are separated by, for example, a spacer 113 to electrically isolate the NFET 111 and the PFET 112. The spacer 113 is, for example, silicon nitride or silicon carbide nitride.

The substrate 101 includes a silicon (Si) substrate, a substrate formed of a material including silicon, a substrate formed of a III-V compound semiconductor material, a silicon-on-insulator (SOI) substrate, a germanium (Ge) substrate, silicon germanium (SiGe) substrate, or other types of semiconductor substrates. The aforementioned III-V compound semiconductor material is, for example, gallium arsenide (GaAs). The substrate 101 may include a ring-shaped/circular substrate or the like having a diameter of about 200 mm, a diameter of about 300 mm, or other diameters.

The transistor structure 104 may include an active region with one or more semiconductor layers 109. In some embodiments, the semiconductor layer 109 includes a silicon (Si) material or another elemental semiconductor material such as germanium (Ge). In some embodiments, the semiconductor layer 109 includes an alloy semiconductor material, such as silicon germanium (SiGe), gallium arsenide phosphide (GaAsP), aluminum indium arsenide (AlInAs), arsenide Aluminum gallium arsenide (AlGaAs), gallium indium arsenide (GaInAs), gallium indium phosphide (GaInP), gallium indium arsenide phosphide (GaInAsP) or combinations thereof. In some embodiments, the semiconductor layer 109 can be doped with n-type and/or p-type dopants.

The transistor structure 104 can be fabricated by suitable semiconductor process techniques, such as masking, optical lithography, and/or etching processes. As an example, the fin-based structure 102 may be formed by etching away a portion of the substrate 101 to form a recess in the substrate 101. Then, the groove can be filled with the isolation material that is etched back, so as to form a shallow trench isolation (STI) region 103 on the substrate 101 and between the fin-based structures 102. Other fabrication techniques for the STI region 103, and/or for the fin structures 102 may be used. The STI region 103 can electrically isolate adjacent active regions in the fin-based structure 102. The STI region 103 may include a dielectric material, such as silicon oxide (SiOx), silicon nitride (Si_{X}Ny), silicon oxynitride (SiON), fused silica glass (FSG), low-k dielectric material, and/or other suitable insulating materials. The STI region 103 may include a multi-layer structure, for example with one or more liners.

In some embodiments, the height of the STI region 103 is less than or equal to the height of the fin-based structure 102. In some embodiments, the planarization apparatus performs a planarization (or polishing) operation to planarize the STI region 103 such that the top surface of the STI region 103 is substantially flat and smooth, and such that the top surface of the STI region 103 and the top surface of the fin-based structure 102 have approximately the same height. The planarization operation can increase the uniformity of the STI region 103 formed in the subsequent etch-back operation.

During the etch-back operation, the STI region 103 is etched to expose part of the fin structure 102. In one embodiment, a portion of the STI region 103 may be etched using a plasma etch technique, a wet chemical etch technique, and/or other types of etch techniques.

In some embodiments, adjacent source/drain regions may be shared between the various transistor structures 104. In some embodiments, adjacent source/drain regions may be connected or coupled together such that the fin-based transistor structure 104 in the semiconductor device 100 is implemented as two functional transistors. For example, if adjacent source/drain regions are electrically connected, they can be merged by epitaxial growth (e.g., merging adjacent source/drain regions instead of merging the source/drain regions on both sides of the fin-based structure 102), and two functional transistors can be realized. Other configurations in other examples can implement other numbers of functional transistors.

In some embodiments, the gate dielectric layer 108 may be formed by chemical oxidation, thermal oxidation, atomic layer deposition (ALD), chemical vapor deposition (CVD), and/or other suitable methods. The gate electrode layers 107 may each include a polysilicon layer or other suitable layers. For example, the gate electrode layers 107 can be formed by a suitable deposition process such as LPCVD or PECVD.

As shown in FIG. 2A, the source/drain regions 105 and 106 are formed in recesses of the semiconductor device 100 above the substrate 101. A layer of epitaxial material is deposited in the recess such that a layer of p-type source/drain regions and/or a layer of n-type source/drain regions are formed by epitaxial growth in a specific crystallographic orientation. The material used to form the source/drain regions 105 and 106 (for example, silicon (Si), gallium (Ga), or other types of semiconductor materials) can be doped with p-type dopants (for example, including the dopant type of electron-acceptor atoms that create holes in the material), n-type dopants (for example, a dopant type that includes electron-donor atoms that create mobile electrons in the material), and/or another type of doping. The material can be doped by adding impurities (e.g., p-type dopants, n-type dopants) to the source gases used during epitaxy operations. Examples of p-type dopants that can be used for epitaxial operations include boron (B) or germanium (Ge), etc. The resulting material for the p-type source/drain regions includes silicon germanium (SixGe1-x, where x may range from about 0 to about 100) or another type of p-doped semiconductor material. Examples of n-type dopants that can be used in epitaxial operations include phosphorus (P) or arsenic (As), etc. The resulting material of the n-type source/drain region includes silicon phosphide (SixPy) or another type of n-doped semiconductor material.

In one embodiment, a contact etch stop layer (CESL) is conformally deposited over the source/drain regions 105 and 106 and on surfaces of the gate spacer wall 110a. The CESL can provide a mechanism to stop the etch process while forming contacts 130 (see FIG. 5) or vias on the source/drain regions 105 and 106. The CESL may be formed of dielectric materials that have a different etch selectivity than adjacent layers or elements. The CESL may include or be a nitrogen-containing material, a silicon-containing material, and/or a carbon-containing material. Furthermore, the CESL may include or may be silicon nitride (SixNy), silicon carbon nitride (SiCN), carbon nitride (CN), silicon oxynitride (SiON), silicon carbide (SiCO), or a combination thereof. The CESL may be deposited using a deposition process such as ALD, CVD, or other deposition techniques.

In one embodiment, an interlayer dielectric (ILD) layer is formed on the CESL. The ILD layer is filled in the region above the source/drain regions 105 and 106 and between the gate structures 110. The ILD layer is formed to allow for a replacement gate structure process in the active area, wherein a gate structure 110 is formed in place of the dummy gate structure. The ILD layer may be referred to as an ILD0 layer. After removing the ILD layer and CESL, openings (or recesses) 114 may be left between the gate spacer walls 110a and above the source/drain regions 105 and 106. The dummy gate structures may be removed in one or more etch operations, including plasma etch techniques, which may include wet chemical etch techniques and/or another type of etch technique.

As shown in FIG. 2A, openings (or recesses) 114 are formed through the one or more dielectric layers and to the source/drain regions 105,106. Specifically, the CESL and ILD layers between the gate structures 110 are etched to form openings 114 between the gate structures 110 and above the source/drain regions 105 and 106. In some embodiments, the openings 114 are formed in a portion of the source/drain regions 105 and 106 such that the openings 114 extend into a portion of the source/drain regions 105 and 106. Each of the openings 114 includes a bottom surface corresponding to the top surface S1 of the associated source/drain regions 105 and 106, and a plurality of sidewalls corresponding to side walls of the gate spacer 110a, CESL and/or ILD layers.

In some embodiments, the openings 114 are formed using a pattern in a photoresist layer. In some embodiments, the photoresist layer is formed on the ILD layer and on the gate structure 110 and a portion of the photoresist layer is exposed to a radiation source to pattern the photoresist layer, then the photoresist layer is developed and a portion of the photoresist layer is removed to expose the pattern. The pattern-exposed ILD layer is etched to form the openings 114.

In some embodiments, a pre-cleaning operation is performed to clean surfaces (e.g., bottom surfaces and sidewalls) in opening 114. Specifically, the semiconductor device 100 may be placed in a processing chamber, the processing chamber may be evacuated to at least a partial vacuum, and the surfaces in the openings 114 may be pre-cleaned using a plasma-based, and/or chemical-based pre-cleaner. A pre-clean operation is performed to clean (e.g., remove) oxides and other contaminants or by-products from the top surfaces S1 of the source/drain regions 105 and 106, and/or other surfaces in the opening 114, which may be formed after the opening 114 is formed.

As shown in FIGS. 1B and 2B, a metal silicide layer 120 is formed on the top surface of the source/drain regions 105 and 106 in the first opening 114, that is, the metal silicide layer 120 is formed on a bottom surface in the first opening 114. In addition, the metal silicide layer 120 and a metal oxide 122 are also formed on the surface of the epitaxial layer of the gate structure 110. The metal oxide 122 is also formed on the oxygen-rich surface (e.g., cut-on-poly-oxide-definition-edge (CPODE) refiller 116). In some embodiments, the metal silicide layer 120 may be formed on the source/drain regions 105 and 106 to lower the contact resistance between the source/drain regions 105 and 106 and the conductive structures (e.g., source/drain contacts 130, see FIG. 5) to be formed over the source/drain regions 105 and 106. In addition, the metal silicide layer 120 can protect the source/drain regions 105 and 106 from oxidation and/or other contamination. The metal silicide layer 120 includes a titanium silicide (TiSix) layer or another type of metal silicide.

In some embodiments, CVD, PVD, ALD or other suitable methods can be used to deposit CMG trench refiller or CPODE refiller 116, such as depositing silicon nitride or other materials in the trenches. In addition, the CMG trenches can be formed to a predetermined aspect ratio using an anisotropic etch, which can include a dry etch process or a suitable etch process. For example, the dry etching process can use oxygen-containing gas, hydrogen gas, fluorine-containing gas (for example, CF₄, SF₆, CH₂F₂, CHF₃ and/or C₂F₆), chlorine-containing gas (for example, Cl₂, CHCl₃, CCl₄ and/or BCl₃), Bromine-containing gas (e.g., HBr and/or CHBr₃), iodine-containing gas, other suitable gases and/or plasma and/or combinations thereof.

In some embodiments, the metal silicide layer 120 is formed, for example, in a soaking process that is performed as part of a plasma-based deposition process, such as LPCVD or PECVD. The flow of metal precursors, such as titanium precursors (for example, titanium chloride (TiClx, such as TiCl₄) or another type of titanium precursor is used so that titanium (Ti) in titanium chloride, silicon (Si) in the source/drain regions 105 and 106, hydrogen (H₂) in the reaction gas and plasma (excluding nitrogen, N₂) can react to selectively form a metal silicide layer 120 (for example, a titanium silicide (TiSix) layer) on the top surface S1 of the source/drain regions 105 and 106.

In some embodiments, the plasma-based deposition process may be performed at a temperature in the range of about 300 degrees Celsius to about 500 degrees Celsius to provide sufficient metal silicide formation and maintain a sufficiently low titanium deposition rate.

As shown in FIGS. 1B and 2B, in a plasma-based deposition process, a metal oxynitride or metal oxide 122 could cover the metal silicide layer 120. The metal silicide layer 120 may mainly include silicon and titanium. The metal silicide layer 120 may also include other elements, such as ruthenium (Ru), nitrogen (N₂) and/or oxygen (O₂). Since the metal oxynitride or metal oxide 122 is formed on the metal silicide layer 120 during the formation of the metal silicide layer 120, in one embodiment, as shown in FIGS. 1C and 2C, hydrofluoric (HF) acid, fluoride ions or other etching materials is used to remove the metal oxide 122 covering the source/drain regions 105 and 106, remove the metal oxide 122 formed on the surface of the spacer wall 110a of the gate structure 110 or the N-rich surface (such as the sidewalls of the groove or the CMG trench refiller), removing the metal oxide 122 formed on the oxygen-rich surface (e.g., CPODE refiller 116). After removing the metal oxide 122 (such as TiOx) covering the source/drain regions 105 and 106, the silicide contact resistance between the source/drain regions 105 and 106 and conductive structures (e.g., source/drain contacts 130) to be formed on the source/drain regions 105 and 106 can be lowered.

As shown in FIGS. 1D and 2D, a reaction gas is introduced to react the metal silicide layer 120 (such as TiSix), hydrogen (H₂) in the reaction gas and plasma (nitrogen, N₂), to form a metal silicon nitride layer 124 (for example, TiSixNy) on the metal silicide layer 120. That is to say, the metal silicon nitride layer 124 is formed on the surface of the metal silicide layer 120 through a nitriding process to prevent the metal silicide layer 120 from being oxidized.

Subsequently, as shown in FIG. 5, a source/drain contact 130 may be formed on the source region 105 or the drain region 106 of the field effect transistor. Each source/drain contact 130 may comprise a single metal layer or a stack of metal layers. The stack of metal layers may include different metals from each other. In some embodiments, the source/drain contact 130 may include any suitable conductive material, such as cobalt, tungsten, ruthenium, titanium, silver, aluminum, titanium aluminum nitride, tantalum carbide, tantalum carbonitride, silicon nitride Tantalum, manganese, zirconium, titanium nitride, tantalum nitride, molybdenum, tungsten nitride, copper, nickel, titanium carbide, titanium aluminum carbide, tantalum aluminum carbide, metal alloys, or combinations thereof. The source/drain contact 130 may be formed by atomic layer deposition (ALD), physical vapor deposition (PVD), chemical vapor deposition (CVD), or other suitable conductive material deposition processes.

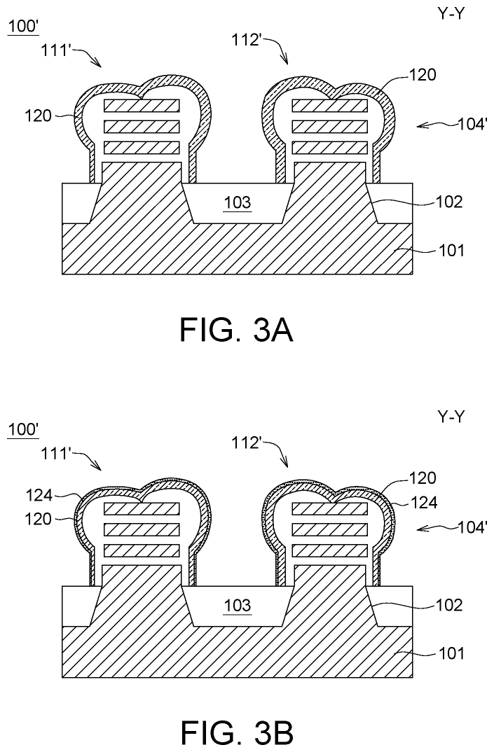

Referring to FIGS. 3A and 3B, schematic views of a semiconductor device 100′ in a cross-sectional direction according to another embodiment of the present disclosure are illustrated. In some embodiments, the transistor structure 104′ includes an n-type gate-all-around (GAA) field effect transistor 111′ and a p-type gate-all-around (GAA) field effect transistor 112′. As shown in FIG. 3A, the n-type gate-all-around (GAA) field effect transistor 111′ and the p-type gate-all-around (GAA) field effect transistor 112′ are, for example, separated by a shallow trench isolation (STI) region. 103, so that the n-type gate-all-around (GAA) field effect transistor 111′ is electrically isolated from the p-type gate-all-around (GAA) field effect transistor 112′.

In addition, referring to FIG. 3B, the semiconductor device 100′ further includes a metal silicide layer 120 and a metal silicon nitride layer 124 formed on the transistor structure 104′. For each process stage of the metal silicide layer 120 and the metal silicon nitride layer 124, referring to the above descriptions in FIGS. 1A to 1D and FIGS. 2A to 2D. The metal silicide layer 120 is formed on the top surface of the source region 105 and the top surface of the drain region 106. In addition, the metal silicide layer 120 is also formed on the surface of the epitaxial layer of the gate structure 110. Since the metal oxynitride or metal oxide 122 is formed on the metal silicide layer 120 during the formation of the metal silicide layer 120, in one embodiment, hydrofluoric acid or fluorine ion is used to remove the metal oxide 122 on the source/drain regions 105 and 106, remove the metal oxide 122 formed on the surface of the spacer wall 110a of the gate structure 110, and remove the metal oxide 122 formed on the oxygen-rich surface. After removing the metal oxide 122 (such as TiOx) covering the source/drain regions 105 and 106, a reaction gas is introduced to make the metal silicide layer 120 (such as titanium silicide, TiSix), hydrogen (H₂) in the reaction gas and plasma (including nitrogen, N₂) react to form a metal silicon nitride layer 124 (for example, titanium silicon nitride (TiSixNy)) on the metal silicide layer 120. That is to say, the metal silicon nitride layer 124 is formed on the surface of the metal silicide layer 120 through a nitriding process to prevent the metal silicide layer 120 from being oxidized.

In one embodiment, the thickness of the metal silicide layer 120 is between 2 nm and 4 nm, and the thickness of the metal silicon nitride layer 124 is between 1 nm and 4 nm. That is to say, the total thickness of the metal silicide layer 120 and the metal silicon nitride layer 124 is, for example, between 3 nm and 8 nm. In one embodiment, the increase in the thickness of the metal silicide layer 120 and the metal silicon nitride layer 124 is gradual, continuous, and/or uniform, such as the thickness of the metal silicide layer 120 and the metal silicon nitride layer 124 decreases sequentially from the center of epitaxial layer to both sides, and the contact area with the source/drain contact 130 passing through the ILD layer 132 increases and the contact shape is a spine-like, which makes it possible to reduce the contact resistance between the source/drain contact 130 and the source/drain regions 105 and 106.

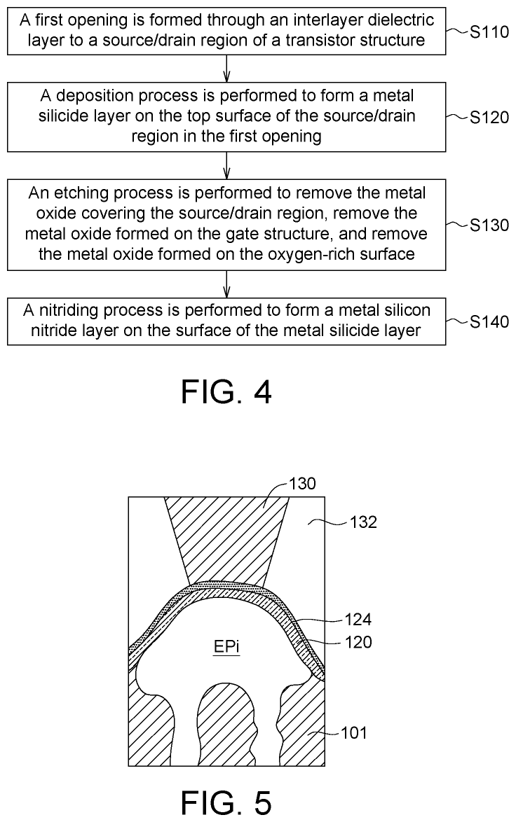

According to the above description, a method for forming a semiconductor device 100 is provided. As shown in FIG. 4, the method includes the following steps S110-S140. First, a first opening is formed through an ILD layer to a source/drain region of a transistor structure. As mentioned above, the openings (or recesses) 114 are formed through the one or more dielectric layers to the source/drain regions 105 and 106. Specifically, the CESL and ILD layer between the gate structures 110 are etched to form openings 114 between the gate structures 110 and above the source/drain regions 105 and 106.

Next, in step S120, a deposition process is performed to selectively form a metal silicide layer 120 on the top surface of the source/drain regions in the first opening. As mentioned above, a plasma-based deposition process is performed to selectively form a titanium silicide (TiSix) layer on the top surfaces of the source/drain regions 105 and 106 in the first openings 114. In one embodiment, the step of performing a plasma-based deposition process includes providing a flow of titanium chloride (TiClx) and a reaction gas (H₂) into the first openings 114, and providing a plasma into the first openings 114, wherein titanium (Ti) of titanium chloride, the silicon of the source/drain regions 105 and 106, the hydrogen in the reaction gas, and the plasma (excluding nitrogen, N₂) react to select the source/drain in the first opening. A titanium silicide (TiSix) layer is formed on top surfaces of the electrode regions 105 and 106. In one embodiment, the plasma in the plasma-based deposition process bombards the source/drain regions 105 and 106, which results in the formation of mobile silicon atoms in the source/drain regions 105 and 106, and the mobile silicon atoms diffuse to the top surface of the source/drain regions 105 and 106, where the mobile silicon atoms react with titanium chloride to form a titanium silicide layer.

Next, in step S130, an etching process is performed, such as using hydrofluoric acid, fluoride ions or other etching materials (such as tetrabutylammonium fluoride (TBAF) or Tetramethylammonium fluoride (TMAF)) to remove the metal oxide 122 (such as TiOx) covering on the source/drain regions 105 and 106, remove the metal oxide 122 (such as TiOx) formed on the surface of the spacer wall 110a of the gate structure 110, and remove the metal oxide 122 (such as TiOx) formed on the oxygen-rich surface. Since the etching rate of hydrofluoric acid to metal oxide 122 (such as TiOx) is much greater than the etching rate of hydrofluoric acid to metal silicide (such as TiSix), the metal silicide layer 120 covering on the source/drain regions 105 and 106 (such as TiSix) may be retained and only the metal oxide 122 (such as TiOx) is removed.

Next, in step S140, a nitriding process is performed to form a metal silicon nitride layer 124 on the metal silicide layer 120. As mentioned above, the reaction gas is passed through to make the metal silicide layer 120 (such as TiSix), the hydrogen (H₂) in the reaction gas and the plasma (including nitrogen, N₂) react, so that the metal silicon nitride layer 124 (such as TiSixNy) is formed on metal silicide layer 120 (such as TiSix).

Since the metal silicon nitride layer 124 (such as TiSixNy) has a high oxygen barrier capability, there is no need to additionally form at least one of a titanium nitride (titanium nitride, TixNy) barrier layer or a tantalum nitride (TaxNy) barrier layer on the metal silicide layer 120 (such as TiSix). Therefore, according to the above-mentioned method of forming the semiconductor device 100, 100′, it can be seen that the titanium precursor is used to selectively form a titanium silicide (TiSix) layer in the semiconductor device 100, 100′. For example, a plasma-based deposition process is performed in which a titanium precursor is provided into the openings and silicon is diffused to the top surface of the transistor structure 104 using a reaction gas and a plasma. The diffusion of silicon results in the formation of a silicon-rich surface of the transistor structure 104, which increases the selectivity of titanium silicide formation relative to other surfaces of the semiconductor device 100. The titanium precursor reacts with the silicon-rich surface to form a titanium silicide layer, and a titanium silicon nitride (TiSixNy) barrier layer is formed on the surface of the titanium silicide layer. This enables the formation of conductive structures such as metal source/drain contacts 130 in the openings without adding another barrier layer.

According to the above-mentioned method of forming the semiconductor device 100, 100′, the effective area of N-type or P-type source/drain regions (i.e., epitaxy region (EPi) in FIG. 5) during the TiSi or TiSixNy formation is increased, as shown in FIG. 5 and the residual Ti(N) deposition on the other surfaces, e.g. STI region, trench wall, metal gate, low k spacer, CPODE or CMG re-filling SiN and etc. are removed after TiSi formation. In one embodiment, TiSi formation on N-type or P-type source/drain region is wrap-around like (i.e., spine like), which increase 20%˜30% area than conventional concave bowl-like TiSi. As shown in FIG. 5, the source/drain contact 130 is electrically connected to the source/drain regions through the metal silicide layer 120 and the metal silicon nitride layer 124, because the metal silicide layer 120 is a spine-like shape to increase the contact area, thus reducing the contact resistance between the source/drain regions and the conductive structure (e.g., source/drain contact 130) to be formed on the source/drain regions.

In addition, in the conventional fabrication, Ti on non-functional region will be removed by wet clean. However, Ti deposition on SiN or N-rich surface is difficultly removed by bulk chemicals (e.g.: SC1, SC2, H₂O₂, HF, H₂SO₄, H₃PO₄ and etc.). Even through Ti on N-rich surface can be removed, the metal gate or TiSi on epitaxy region will be damaged by chemicals. Compared to conventional fabrication, in the present disclosure, the forming method can reduce the Ti residue on sidewall or on inactive regions, so that the silicide contact resistance would be decreased and improve the performance of the semiconductor device 100, 100′.

The present disclosure relates to a semiconductor device and a method of forming the semiconductor device, which can reduce the Ti residue on sidewall or on inactive regions during the TiSi formation, and titanium silicon nitride (TiSixNy) barrier layer is formed on the surface of the titanium silicide layer, which enables the formation of conductive structures such as source/drain contacts in the openings without adding another barrier layer, so that the silicide contact resistance would be decreased and the performance of the semiconductor device is improved.

According to some embodiments of the present disclosure, a semiconductor device is provided, including a substrate, a transistor structure, a metal silicide layer, and a metal silicon nitride layer. The transistor structure is formed on the substrate. The transistor structure includes a source region, a drain region and a gate structure. The gate structure is located between the source region and the drain region. The metal silicide layer is formed on the top surface of the source region and the top surface of the drain region, and the metal silicon nitride layer is formed on the surface of the metal silicide layer.

According to some embodiments of the present disclosure, a method of forming a semiconductor device is provided, including forming a first opening through an interlayer dielectric layer to a source/drain region of a transistor structure. A deposition process is performed to form a metal silicide layer on the top surface of the source/drain region in the first opening. A nitriding process is performed to form a metal silicon nitride layer on the surface of the metal silicide layer.

According to some embodiments of the present disclosure, a barrier layer is provided, including a metal silicide layer and a metal silicon nitride layer. The metal silicide layer is formed on a source/drain region, the metal silicon nitride layer covers the metal silicide layer, and the metal silicide layer is treated by a nitriding process to form the metal silicon nitride layer on the surface of the metal silicide layer.

According to some embodiments of the present disclosure, a method of forming a semiconductor device is provided. A deposition process is performed to selectively form a metal silicide layer on a top surface of the source/drain region. A nitriding process is performed to form a metal silicon nitride layer on a surface of the metal silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a transistor structure formed on the substrate, the transistor structure comprising a source region, a drain region and a gate structure, and the gate structure being located between the source region and the drain region;
a metal silicide layer formed on a top surface of the source region and a top surface of the drain region; and
a metal silicon nitride layer formed on a surface of the metal silicide layer.

2. The semiconductor device according to claim 1, further comprising a source/drain contact, wherein the source/drain contact is electrically connected to the source region or the drain region through the metal silicide layer and the metal silicon nitride layer.

3. The semiconductor device according to claim 1, wherein the metal silicide layer comprises titanium silicide, and a shape of the metal silicide layer is spine-like.

4. The semiconductor device according to claim 1, wherein the metal silicon nitride layer comprises titanium silicon nitride.

5. A method of forming a semiconductor device, comprising:
forming a first opening through the interlayer dielectric layer to a source/drain region of a transistor structure;
performing a deposition process to selectively form a metal silicide layer on a top surface of the source/drain region in the first opening; and
performing a nitriding process to form a metal silicon nitride layer on a surface of the metal silicide layer.

6. The method according to claim 5, wherein when forming the metal silicide layer, the method further comprises forming the metal silicide layer and a metal oxide on an epitaxial surface of the gate structure, and forming a metal oxide on a sidewall of a gate spacer and forming a metal oxide on an oxygen-rich surface.

7. The method according to claim 6, wherein after forming the metal silicide layer and prior to the nitriding process, the method further comprises performing an etching process to remove the metal oxide covering the source/drain region, remove the metal oxide formed on the gate structure, and remove the metal oxide formed on the oxygen-rich surface.

8. The method according to claim 7, wherein the oxygen-rich surface comprises a cut metal gate (CMG) trench refiller and a cut-on-poly-oxide-definition-edge (CPODE) refiller.

9. The method according to claim 7, wherein the etching process comprises removing the metal oxides with hydrofluoric acid, tetrabutylammonium fluoride (TBAF) or Tetramethylammonium fluoride (TMAF).

10. The method according to claim 9, wherein an etching rate of the metal oxide is greater than an etching rate of the metal silicide in the etching process.

11. The method according to claim 5, wherein the nitriding process comprises providing a reaction gas to make the metal silicide layer, hydrogen in the reaction gas and nitrogen react to form the metal silicon nitride layer.

12. The method according to claim 5, wherein forming the metal silicide layer comprises reacting a titanium precursor with a silicon-rich surface to form a titanium silicide layer.

13. The method according to claim 12, wherein forming the metal silicon nitride layer comprises forming a titanium silicon nitride layer on the surface of the titanium silicide layer.

14. The method according to claim 5, wherein the metal silicide layer covers the top surface of the source/drain region, and a shape of the metal silicide layer is spine-like.

15. A method of forming a semiconductor device, comprising:
performing a deposition process to selectively form a metal silicide layer on a top surface of the source/drain region; and
performing a nitriding process to form a metal silicon nitride layer on a surface of the metal silicide layer.

16. The method according to claim 15, wherein when forming the metal silicide layer, the method further comprises forming a metal oxide on an epitaxial surface of the gate structure, and performing an etching process to remove the metal oxide formed on the gate structure.

17. The method according to claim 15, wherein the metal silicide layer comprises titanium silicide.

18. The method according to claim 15, wherein the metal silicon nitride layer comprises titanium silicon nitride.

19. The method according to claim 15, wherein the nitriding treatment comprises providing a reaction gas to make the metal silicide layer, hydrogen in the reaction gas and nitrogen react to form the metal silicon nitride layer on the surface of the metal silicide layer.

20. The method according to claim 15, wherein a shape of the metal silicide layer is spine-like.
